(19) United States
(12) Patent Application Publication
(10) Pub. No.: US 2012/0158331 A1
(43) Pub. Date: Jun. 21, 2012

(54) Power Input Efficiency Measurement Method

(76) Inventors: Chih-Hsiang Chung, Hsinchu (TW); Feng-Jen Chang, Hsinchu (TW); Hsuang-Chang Chiang, Hsinchu (TW)

(21) Appl. No.: 13/299,476

(22) Filed: Nov. 18, 2011

(30) Foreign Application Priority Data
Dec. 16, 2010 (TW) 099144136

(51) Int. Cl. G06F 19/00; G01R 19/00

(52) U.S. Cl. 702/64; 324/76.11

(57) ABSTRACT

A power input efficiency measurement method includes: providing a power source to supply to a power input system that has a power converter; measuring a current at a primary side of the power converter; measuring a voltage at the primary side of the power converter; and calculating the primary-side current and the primary-side voltage to obtain power efficiency of the power input system. In a preferred embodiment, a current transformer unit is applied to measure the primary-side current while a negative-voltage conversion circuit is applied to measure the primary-side voltage.

### BACKGROUND OF THE INVENTION

1. Field of the Invention

The present invention relates to a power input efficiency measurement method. More particularly, the present invention relates to the power input efficiency measurement method for measuring a systematic efficiency of a power supply.

2. Description of the Related Art

In general, flyback converters have a circuitry structure of a buck-boost converter which provides a characteristic of electrical isolation. The circuitry structure of the flyback converter has several advantages of low cost, well developed technique and simpler structures. Furthermore, the flyback converter can also achieve multiple output purposes so that it will be widely used in auxiliary power supply design for supplying auxiliary power to the whole system. Yet further, with respect to the design of the flyback converter, it is not necessitated to provide a performance of electrical isolation with equipped electrical appliances.

Although the electrical isolation is not a necessary design of the flyback converter, there exists a need of enhancing and ensuring safety use. To this end, between input and output terminals is electrically isolated. A transformer design is usually used to perform as an isolated converter. In circuit design, the isolated converter is operated to separately form a high voltage side and a low voltage side of the flyback converter.

FIG. 1 shows a schematic diagram of a simulation circuit operated by a conventional method for measuring input power efficiency in accordance with the prior art. Referring to FIG. 1, when measuring a systematic efficiency η of input power, there must provide an input power value pin(t) of a primary side and an output power value po(t) of a secondary side that results in several design limits. Briefly, to obtain the systematic efficiency η of input and output power, the input power value pin(t) and the output power value po(t) must be separately and synchronously measured at the primary side and the secondary side of the power system, respectively that is a step-by-step measurement process.

In the case of the flyback converter, although the method of separately measuring the input power value pin(t) at a primary side and the output power value po(t) at a secondary side can also be used to calculate the systematic efficiency η, there is a potential need of further providing other methods for measuring the efficiency η of the system in a manner to improve the problem of design limits and sophisticated measuring steps.

Taiwanese patent publication No. 1316659, entitled “apparatuses and Method for Adjusting System Performance,” discloses an apparatus for adjusting system performance, comprising a system current detector and a system performance adjustment module. The apparatus is applied to a system provided with power consumption components. The system current detector is used to receive systematic current values, thereby calculating current variations of the systematic current values. The system performance adjustment module is used to receive the systematic current variations and to generate a frequency control signal and a voltage control signal depending on the systematic current variations. However, it fails to disclose an improved method of measuring power efficiency.

Further, U.S. Pat. No. 6,614,133, as well as U.S. patent publication No. 20030080624, entitled “power system with plural parallel power supplies with at least one power supply in standby mode for energy efficiency,” discloses a power system having multiple power supplies with outputs connected in parallel. The number of supplies providing current is controlled to improve the overall system efficiency. However, it also fails to disclose an improved method of measuring power efficiency.

Yet further, U.S. patent publication No. 20090296432, entitled “apparatus and method of optimizing power system efficiency using a power loss model,” discloses a power subsystem which is actively optimized to improve total subsystem efficiency in a way that is responsive to changes in load requirements, power supply variations, and subsystem temperature variations. However, it also fails to disclose an improved method of measuring power efficiency.

Yet further, U.S. patent publication No. 20080122543, entitled “switching power supply,” discloses methods and systems for enhancing system efficiency in a power amplification, modulation, and transmission system. The output stage power supply of the system is controlled to operate at substantially optimal efficiency at the most probable output power point of operation. However, it also fails to disclose an improved method of measuring power efficiency.

Each of the above-mentioned patent application publications and issued patents is incorporated herein by reference for purposes including, but not limited to, indicating the background of the present invention and illustrating the state of the art.

As is described in greater detail below, the present invention provides a power input efficiency measurement method for power systems. The power input efficiency measurement method requires only processing measurement operation at a primary side of a power converter in such a way as to mitigate and overcome the above problem.

### SUMMARY OF THE INVENTION

The primary objective of this invention is to provide a power input efficiency measurement method. A current i(t) is measured at a primary side of a power converter by a current transformer and a voltage v(t) is further measured at the primary side by a negative-voltage conversion circuit such that a power output efficiency at a second side of the power converter can be calculated. Accordingly, the power input efficiency measurement method is successful in simplifying the entire measurement procedure.

The power input efficiency measurement method in accordance with an aspect of the present invention includes:

providing a power source to supply to a power input system that has a power converter;

measuring a current at a primary side of the power converter;

measuring a voltage at the primary side of the power converter; and

calculating the primary-side current and the primary-side voltage to obtain power efficiency of the power input system.

In an aspect of the present invention, the primary-side current is measured by a current transformer unit.

In a separate aspect of the present invention, the primary-side voltage is measured by a negative-voltage conversion circuit.

In a further separate aspect of the present invention, the power converter is selected from a flyback converter.

In yet a further separate aspect of the present invention, the power converter further includes an isolation transformer.

In yet a further separate aspect of the present invention, a power electronic simulation procedure is applied to simulate a power output.

In yet a further separate aspect of the present invention, the power electronic simulation procedure is implemented by PSIM simulation software.

Further scope of the applicability of the present invention will become apparent from the detailed description given hereinafter. However, it should be understood that the detailed description and specific examples, while indicating preferred embodiments of the invention, are given by way of illustration only, since various modifications will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a schematic diagram of a simulation circuit operated by a conventional method for measuring input power efficiency in accordance with the prior art.

FIG. 2 is a schematic diagram of a simulation circuit operated by a power input efficiency measurement method in accordance with a preferred embodiment of the present invention.

FIG. 3 is a schematic diagram of a simulation circuit of a current transformer unit applied in the power input efficiency measurement method in accordance with the preferred embodiment of the present invention to measure currents at a primary side of a power converter.

FIG. 4 is a waveform diagram showing simulation currents measured at the primary side of the current transformer unit utilized in the power input efficiency measurement method in accordance with the preferred embodiment of the present invention.

FIG. 5 is waveform diagrams showing voltages of the primary side and the secondary side of the power converter with a conducted power switch utilized in the power input efficiency measurement method in accordance with the preferred embodiment of the present invention.

FIG. 6 is a schematic diagram of a simulation circuit of a negative-voltage conversion circuit applied in the power input efficiency measurement method in accordance with the preferred embodiment of the present invention to measure voltages at the primary side of the power converter.

FIG. 7 is a waveform diagram showing simulation voltages measured at the primary side and the secondary side of the power converter utilized in the power input efficiency measurement method in accordance with the preferred embodiment of the present invention.

FIG. 8 is a schematic diagram of a simulation circuit of a current transformer unit applied in the power input efficiency measurement method in accordance with the preferred embodiment of the present invention to measure currents of utility power at the primary side of the power converter.

FIG. 9 is waveform diagrams showing a simulation current of utility power at the primary side and a simulation voltage at the secondary side of the power converter utilized in the power input efficiency measurement method in accordance with the preferred embodiment of the present invention.

FIG. 10 is a schematic diagram of a simulation circuit of a push-pull circuit applied in the power input efficiency measurement method in accordance with the preferred embodiment of the present invention to measure voltages of utility power at the primary side of the power converter.

FIG. 11 is waveform diagrams showing simulation voltages at the primary side of the power converter measured by the push-pull circuit utilized in the power input efficiency measurement method in accordance with the preferred embodiment of the present invention.

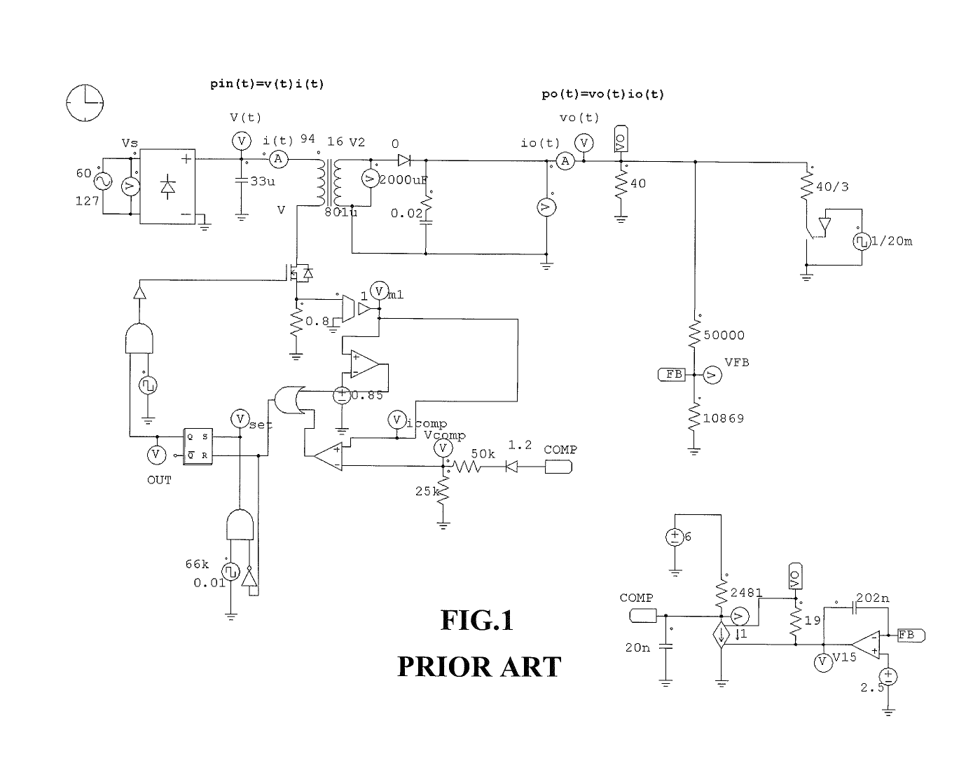

### DETAILED DESCRIPTION OF THE INVENTION

It is noted that a power input efficiency measurement method in accordance with the preferred embodiment of the present invention is suitable for measuring and calculating power efficiency η of power supplies applied in various power input systems or the likes which are not limitative of the present invention.

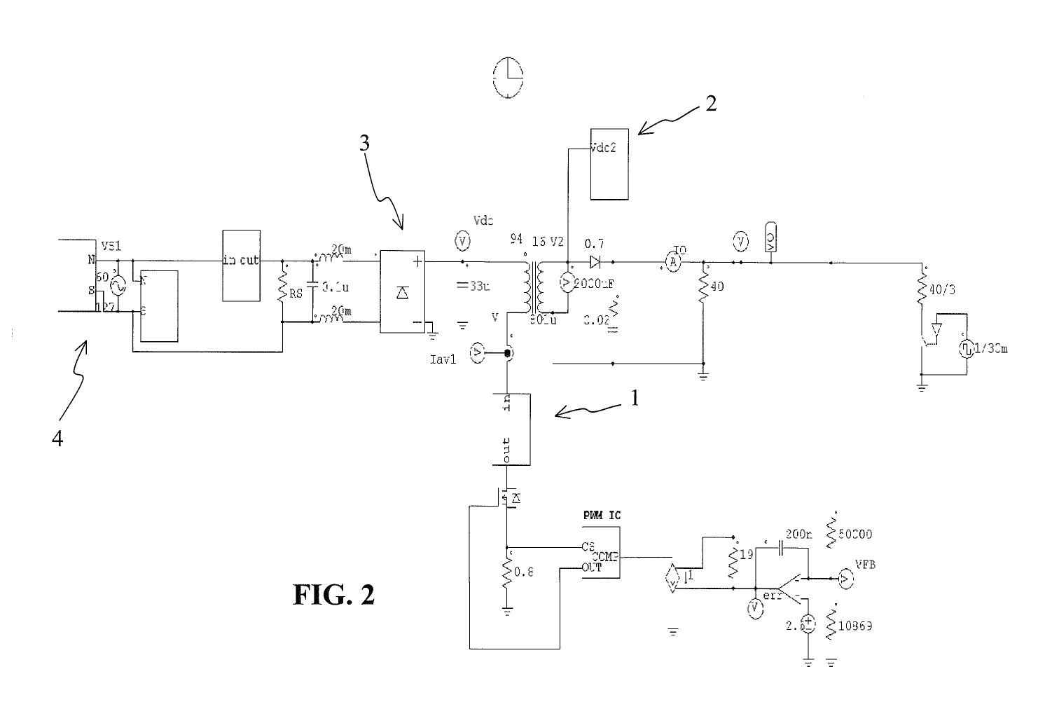

FIG. 2 shows a schematic diagram of a simulation circuit operated by a power input efficiency measurement method in accordance with a preferred embodiment of the present invention. Referring to FIG. 2, the power input efficiency measurement method of the present invention includes the step of: providing a power supply to a power input system which has a power converter or other power electronic converters (e.g. flyback converter). By way of example, a proper power source (e.g. utility power) supplies power to the power input system. In a preferred embodiment, a power electronic simulation procedure is applied to simulate a power output. For example, the power electronic simulation procedure is implemented by PSIM simulation software.

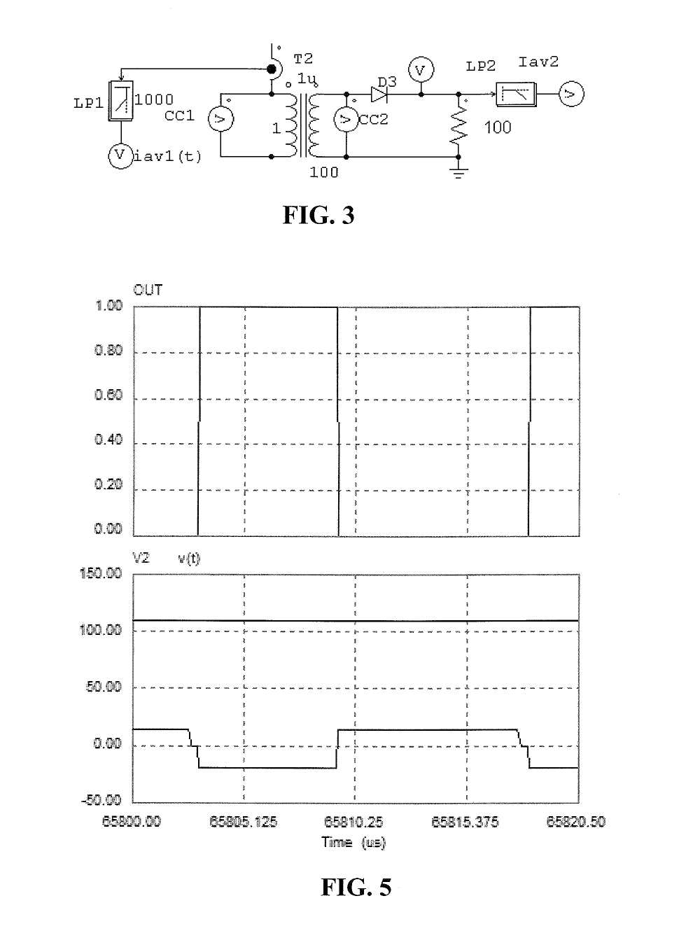

Turning now to FIG. 3, a schematic diagram of a simulation circuit of a current transformer unit applied in the power input efficiency measurement method in accordance with the preferred embodiment of the present invention to measure currents at a primary side of a power converter is shown. Referring to FIGS. 2 and 3, the power input efficiency measurement method of the present invention further includes the step of: measuring a current at a primary side of the power converter. As best shown in FIG. 2, there provides a first measuring position 1 to process measuring a current. Referring again to FIG. 3, a current transformer T2 is applied to measure a current at the primary side of the power converter.

With continued reference to FIG. 3, an average power p(t) is the product of an average input voltage v(t) and an average input current i(t). Since the average input current i(t) is a power switch current, a ratio LP1/LP2 (LP: low-pass filter) is applied to calculate a ratio of average current iav1/iav2 (iav: average current). In the current transformer T2, an input current i(t) is detected at a primary side CC1 and a transformer is applied to convert it into a current of 1/100*i(t) at a side CC2. The current of 1/100*i(t) is further converted into a secondary-side voltage i2(t) by a 100-ohm resistor such that the primary-side current i(t) is equal to the secondary-side voltage i2(t).

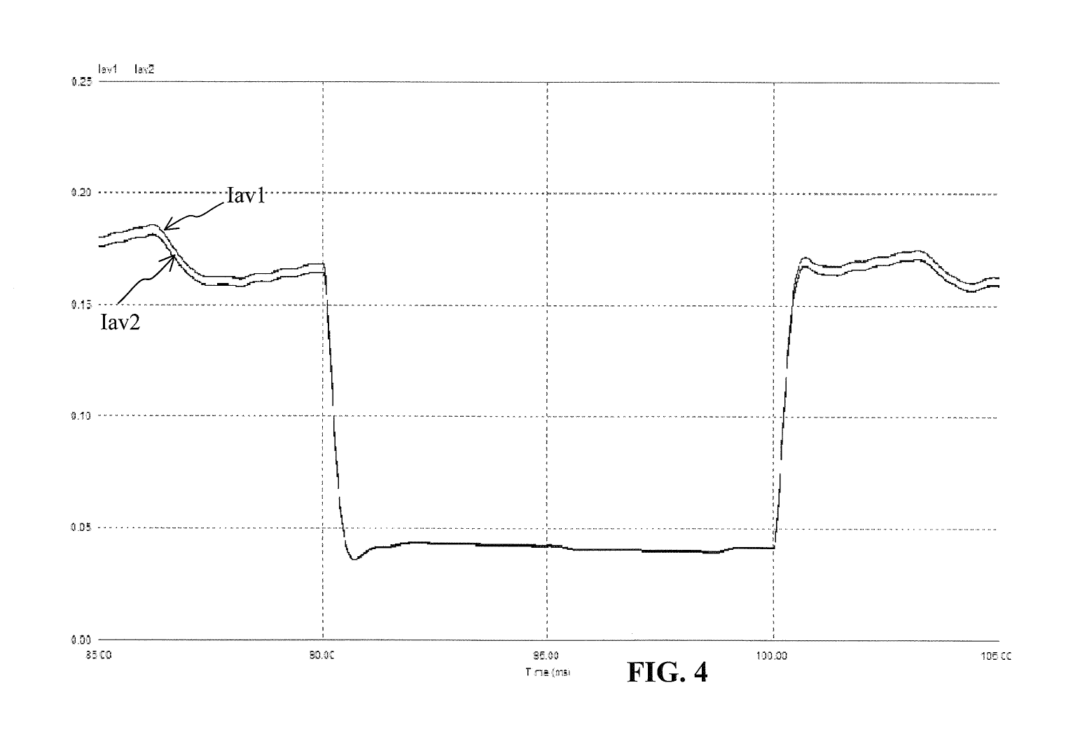

Turning now to FIG. 4, a waveform diagram showing simulation currents measured at the primary side of the current transformer unit utilized in the power input efficiency measurement method in accordance with the preferred embodiment of the present invention is shown. Referring to FIG. 4, a waveform of the primary-side average current iav1 (identified as arrow located in the upper portion in FIG. 4) is similar to that of the secondary-side average current iav1 (identified as arrow located in the lower portion in FIG. 4).

Turning now to FIG. 5, waveform diagrams of voltages of the primary side and the secondary side of the power converter with a conducted power switch utilized in the power input efficiency measurement method in accordance with the preferred embodiment of the present invention are shown. Referring to FIG. 5, when the power switch (corresponding to waveform located in the upper portion in FIG. 5) is conducted, the primary-side voltage v(t) (corresponding to waveform located in the middle portion in FIG. 5) equals the product of the secondary-side voltage V2 (corresponding to waveform located in the lower portion in FIG. 5) and the turn ratio N. Accordingly, the primary-side voltage v(t) can be obtained by converting the secondary-side voltage V2 into a positive voltage and amplifying it N times.

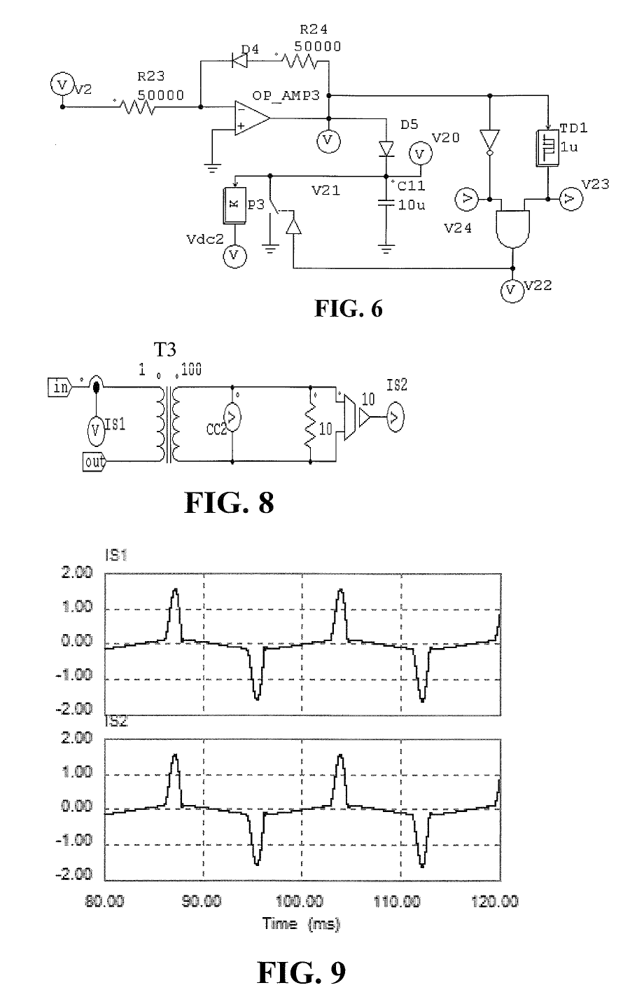

Turning now to FIG. 6, a schematic diagram of a simulation circuit of a negative-voltage conversion circuit applied in the power input efficiency measurement method in accordance with the preferred embodiment of the present invention is shown. Referring to FIGS. 2 and 6, the power input efficiency measurement method of the present invention further includes the step of: measuring a voltage at the primary side of the power converter. As best shown in FIG. 2, there provides a second measuring position 2 to measure a primary-side voltage of the power converter. Referring again to FIG. 6, a negative-voltage conversion circuit is applied to measure the primary-side voltage.

With continued reference to FIG. 6, in the negative-voltage conversion circuit, an OP amplifier OP_AMP3 has a primary-side voltage V2<0, a diode D4 is conducted and the gains of resistors R23 and R24 are considered as −1 such that a voltage amplifier is formed. Finally, the primary-side voltage v(t) equals Vdc2 when the voltage is amplified by a component P3. In addition, a peak-value detection circuit is consisted of a diode D5 and a capacitor C11, wherein the capacitor C11 is periodically charged and discharged by a component V22 such that the peak-value detection circuit has a function of RESET.

After measuring the primary-side current and voltage, the power input efficiency measurement method of the present invention further includes the step of: calculating the primary-side current and the primary-side voltage of the power converter so as to obtain the power efficiency of the power input system.

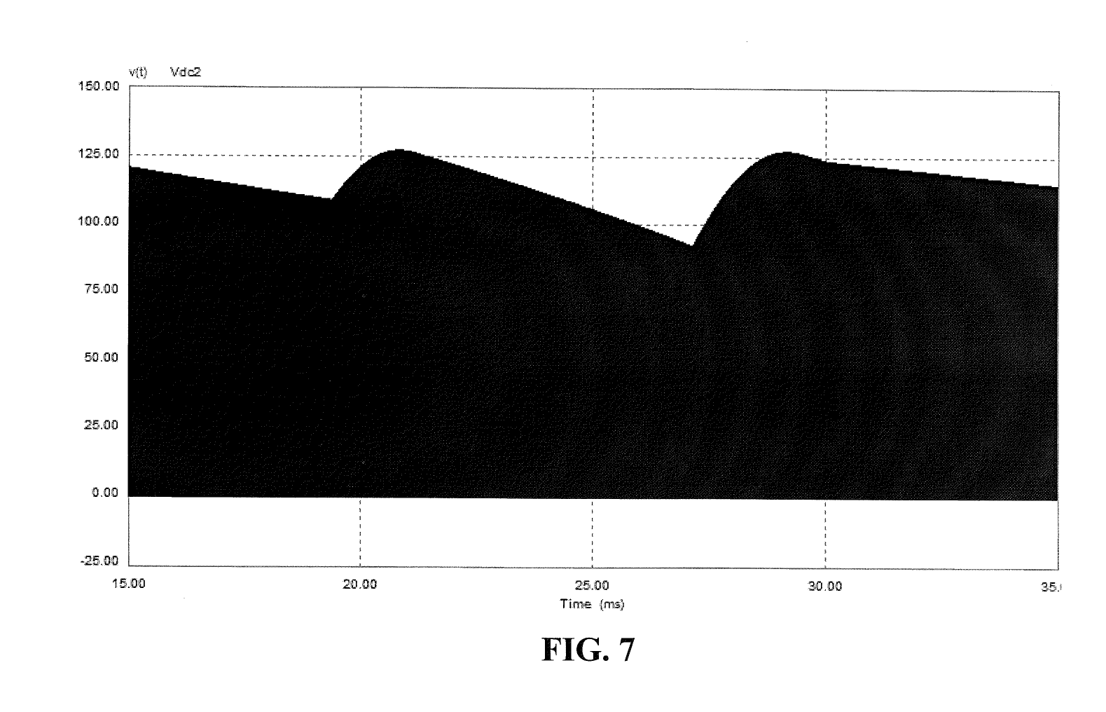

Turning now to FIG. 7, a waveform diagram of simulation voltages measured at the primary side and the secondary side of the power converter utilized in the power input efficiency measurement method in accordance with the preferred embodiment of the present invention is shown. Referring to FIG. 7, the simulation circuit depicted in FIG. 6 is applied to simulate the primary-side voltage v(t) which is identical with a voltage value Vdc2.

Turning now to FIG. 8, a schematic diagram of a simulation circuit of a current transformer unit applied in the power input efficiency measurement method in accordance with the preferred embodiment of the present invention is shown. Referring to FIGS. 2 and 8, the power input efficiency measurement method utilizes a current transformer T3 measuring currents of utility power at the primary side of the power converter at a third measuring position 3, as best shown in FIG. 2.

Referring again to FIG. 8, the current transformer T3 utilized in the power input efficiency measurement method has a first value IS1 at its primary side and a second value IS2 at its secondary side, wherein the first value IS1 equals the second value IS2 (i.e. IS1=IS2). In measuring utility power, the average power p(t) is:

$$p ( t ) = \frac{1}{T} {\int }_{0}^{T} vs ( t ) {is}_{1} ( t ) d t$$

where is1(t) is input utility power (AC 110V or 220V).

The numeral and shape of the average power p(t) are significant in measuring power. The numeral and shape formed from the output voltage IS2 of the current transformer T3 equals those formed from the current IS2 of utility power.

With continued reference to FIG. 8, in the current transformer T3, the input current is1(t) of utility power is detected at the primary side CC1 and converted into a current value of 0.01*is(t) (i.e. 0.01 times the input current is1(t)) at the secondary side. The transformed secondary-side current further pass through a resistor with 10 ohm such that the output secondary-side voltage VCC2 becomes: VCC2=0.01*is1(t)*10, as well as a voltage value is2(t) that is 10 times the transformed secondary-side voltage. Hence, the primary-side current is1(t) equal the secondary-side voltage is2(t).

Turning now to FIG. 9, two waveform diagrams of a simulation current of utility power at the primary side and a simulation voltage at the secondary side of the power converter utilized in the power input efficiency measurement method in accordance with the preferred embodiment of the present invention are shown. The simulation circuit in FIG. 8 provides a simulation current of utility power is1(t) at the primary side, as best shown in the upper portion in FIG. 9, and a simulation voltage at the secondary side, as best shown in the lower waveform in FIG. 9.

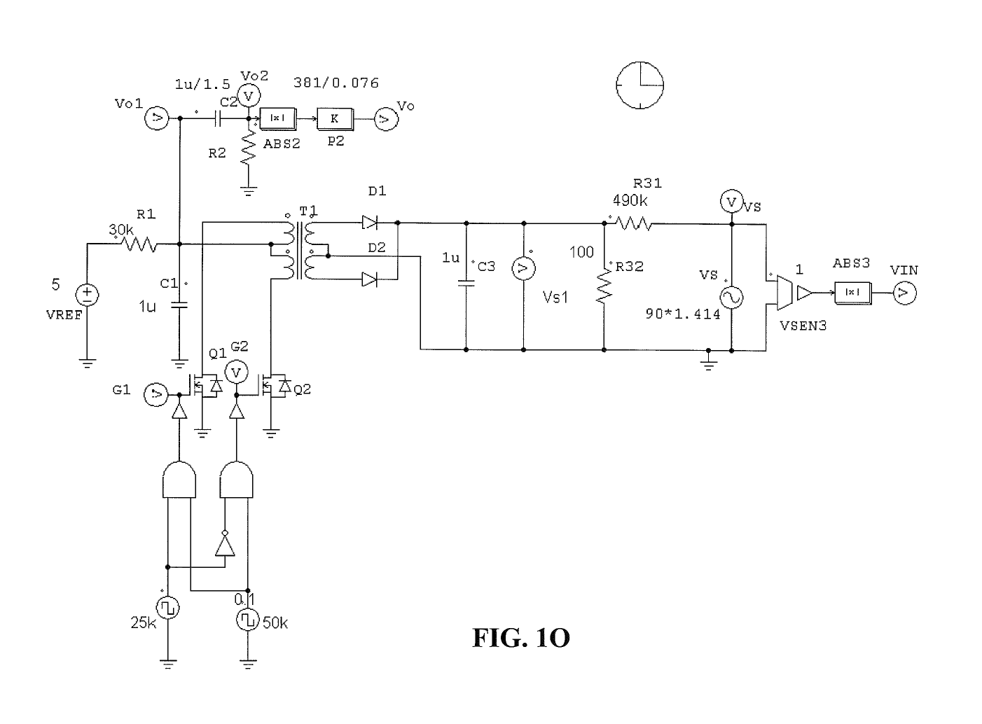

Turning now to FIG. 10, a schematic diagram of a simulation circuit of a push-pull circuit applied in the power input efficiency measurement method in accordance with the preferred embodiment of the present invention is shown. Referring to FIGS. 2 and 10, the power input efficiency measurement method utilizes a push-pull circuit measuring voltages of utility power at the primary side of the power converter at a fourth measuring position 4, as best shown in FIG. 2.

With continued reference to FIG. 10, the push-pull circuit utilized in the power input efficiency measurement method is operated to detect a voltage of utility power. Isolated between the primary side and the secondary side is an isolation transformer T1. In the isolation transformer T1, two resistors R31 and R32 are applied to reduce the voltage VS of utility power and two transistors Q1 and Q2 are applied to generate constant PWM control signals for push-pull operation such that the dimensions of the isolation transformer T1 can be reduced. When the voltage Vo1 of utility power approaches Vs1, the voltage Vo1 may equal the voltage Vs1, wherein the voltage Vo1 is

$${V}_{O 1} = {V}_{REF} \frac{{R}_{32} // {R}_{31}}{{R}_{1} + {R}_{32} // {R}_{31}} + {V}_{S} \frac{{R}_{1} // {R}_{32}}{{R}_{1} // {R}_{32} + {R}_{31}}$$

Furthermore, the capacitors C1 and C3 perform as filters and the phases of the voltage Vo1 will be delayed due to the RC charging and discharging effect. Accordingly, the combination of resistor R2 and capacitor C2 perform as a high-pass filter to precede the phase of the voltage such that the phases of voltage Vo2 of utility power can be adjusted and equals the voltage VS. Furthermore, the voltage Vo2 of utility power is multiplied by P2 in an absolute value circuit to obtain the voltages Vo of utility power and the voltage VS identical with the input voltage VIN of utility power so that the voltage Vo equals the voltage VIN.

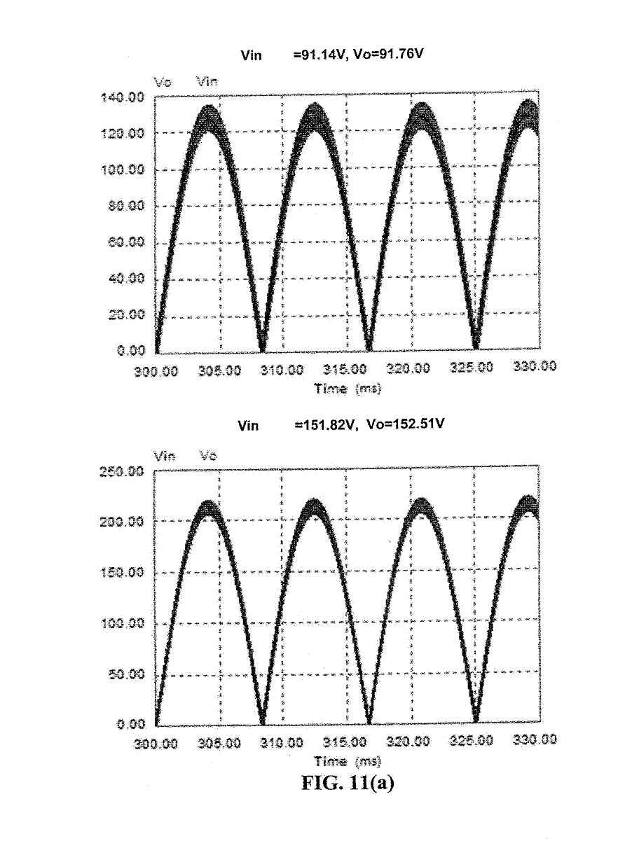

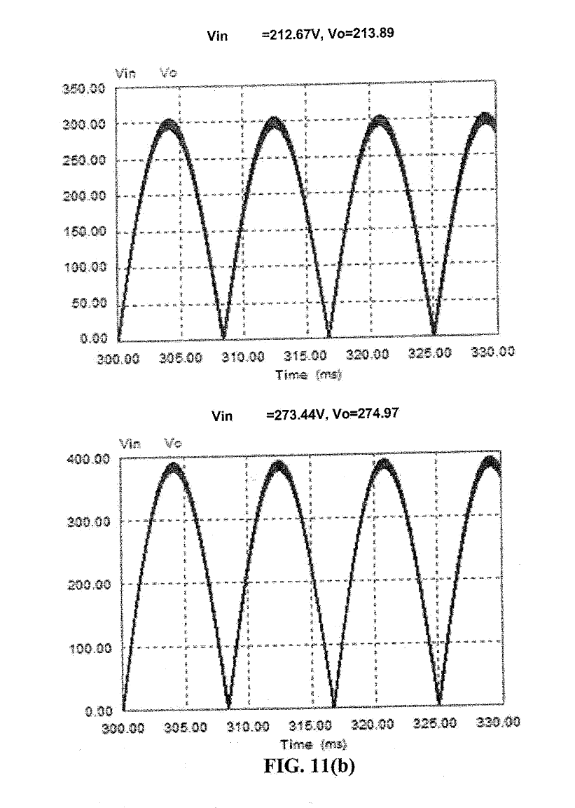

Turning now to FIG. 11, four waveform diagrams of simulation voltages at the primary side of the power converter measured by the push-pull circuit utilized in the power input efficiency measurement method in accordance with the preferred embodiment of the present invention are shown. Referring to FIGS. 10 and 11, the simulation circuit in FIG. 10 provides the input voltage Vin and the voltage Vo of utility power. FIG. 11 shows:

Vin=91.14V while Vo=91.76V,

Vin=151.82V while Vo=152.51V,

Vin=212.67V while Vo=213.89V, and

Vin=273.44V while Vo=274.97V.

where no phase angle difference exists between Vin and Vo.

Although the invention has been described in detail with reference to its presently preferred embodiment(s), it will be understood by one of ordinary skill in the art that various modifications can be made without departing from the spirit and the scope of the invention, as set forth in the appended claims.

What is claimed is:

1. A power input efficiency measurement method, comprising:
providing a power source to supply to a power input system that has a power converter;
measuring a current at a primary side of the power converter;
measuring a voltage at the primary side of the power converter; and
wherein.
calculating the primary-side current and the primary-side voltage to obtain power efficiency of the power input system.

2. The power input efficiency measurement method as defined in claim 1, wherein the primary-side current is measured by a current transformer unit.

3. The power input efficiency measurement method as defined in claim 1, wherein the primary-side voltage is measured by a negative-voltage conversion circuit.

4. The power input efficiency measurement method as defined in claim 1, wherein the power converter is selected from a flyback converter.

5. The power input efficiency measurement method as defined in claim 1, wherein the power converter further includes an isolation transformer.

6. The power input efficiency measurement method as defined in claim 1, wherein a power electronic simulation procedure is applied to simulate a power output.

7. The power input efficiency measurement method as defined in claim 6, wherein the power electronic simulation procedure is implemented by PSIM simulation software.
